(19) United States
(12) Patent Application Publication
(10) Pub. No.: US 2026/0005674 A1
(43) Pub. Date: Jan. 1, 2026

(54) CASCADED COUPLED RESONATOR FILTER SYSTEMS AND METHODS OF OPERATING THE SAME

(71) Applicant: Qorvo US, Inc., Greensboro, NC (US)

(72) Inventors: Kalyan Karnati, Apopka, FL (US); Yazid Yusuf, Orlando, FL (US)

(21) Appl. No.: 19/186,375

(22) Filed: Apr. 22, 2025

Related U.S. Application Data
(60) Provisional application No. 63/665,595, filed on Jun. 28, 2024.

(51) Int. Cl. H03H 9/58; H03H 9/13

(52) U.S. Cl. CPC H03H 9/584; H03H 9/13

(57) ABSTRACT

An acoustic wave filter having a coupled resonator filter is provided. The acoustic wave filter includes an acoustic coupling unit, a first unit of resonators disposed on a first side of the acoustic coupling unit, and a second unit of resonators disposed on a second side, opposite the first side, of the acoustic coupling unit. The first unit of resonators and the second unit of resonators are in an acoustic communication. The first unit of resonators includes a first resonator and a second resonator electrically coupled to the first resonator. The first resonator comprises a first electrode and a second electrode, and wherein the second electrode of the first resonator is disposed adjacent to the acoustic coupling unit and is configured to receive a signal input. A wireless device may include the acoustic wave filter.

### CROSS REFERENCE TO RELATED APPLICATION

This application claims priority to U.S. Patent Application No. 63/665,595, filed Jun. 28, 2024, all of which is incorporated by reference herein in its entirety.

### TECHNICAL FIELD

The present disclosure relates generally to coupled resonator filters, and in particular, relates to coupled resonator filters that include resonators that are configured in a cascaded configuration to provide an improved power handling capability as well as an improved performance in non-linear behavior of the resonators due to the better cancellation of harmonics.

### BACKGROUND

Resonators in a coupled resonator filter (CRF) tend to get smaller in area as the frequency of operation increases. Smaller areas typically lead to a reduction in power handling capabilities of the overall CRF filter. Thus, there is a need to improve power handling capabilities of the CRFs while maintaining operational efficiency and performance while satisfying the miniaturized size required by an increase in operational frequency. Consequently, there is a need for novel approaches and/or device configurations that can help improve the power handling capability of CRFs while also maintain or, perhaps improve, the non-linear performance behavior of the CRFs.

### SUMMARY

Embodiments of the present disclosure include a cascaded coupled resonator filter (CRF) devices and systems, and methods for operating such devices/systems. Aspects of the disclosure advantageously provide device configurations that can help improve power handling capabilities of cascaded CRFs while also maintaining or, perhaps improving, the non-linear performance behavior of the CRFs. Multiple circuits describing various embodiments are provided that use varying types of cascaded CRF configurations.

In an exemplary aspect, an acoustic wave filter is provided. The acoustic wave filter includes an acoustic coupling unit; a first unit of resonators disposed on a first side of the acoustic coupling unit, the first unit of resonators comprising a first resonator and a second resonator electrically coupled to the first resonator; and a second unit of resonators disposed on a second side, opposite the first side, of the acoustic coupling unit such that the first unit of resonators and the second unit of resonators are in an acoustic communication, wherein the first resonator comprises a first electrode and a second electrode, and wherein the second electrode of the first resonator is disposed adjacent to the acoustic coupling unit and is configured to receive a signal input.

In some aspects, the second resonator includes a third electrode and a fourth electrode, and wherein the fourth electrode of the second resonator is disposed adjacent to the acoustic coupling unit and is connected to ground. In some aspects, the first electrode of the first resonator and the third electrode of the second resonator are in an electrical communication. In some aspects, the second unit of resonators comprises a third resonator and a fourth resonator electrically coupled to the third resonator. In some aspects, the third resonator comprises a fifth electrode and a sixth electrode, and wherein the fifth electrode of the third resonator is disposed adjacent to the acoustic coupling unit and is connected to ground. In some aspects, the fourth resonator comprises a seventh electrode and an eighth electrode, and wherein the seventh electrode of the fourth resonator is disposed adjacent to the acoustic coupling unit and configured to provide a signal output. In some aspects, the sixth electrode of the third resonator and the eighth electrode of the fourth resonator are in an electrical communication.

In some aspects, the first unit of resonators, the acoustic coupling unit, and the second unit of resonators form a resonator stack, further comprising: a first acoustic mirror disposed adjacent to the first unit of resonators of the resonator stack and away from the acoustic coupling unit, a second acoustic mirror disposed adjacent to the second unit of resonators of the resonator stack and away from the acoustic coupling unit, or a combination thereof. In some aspects, the first acoustic mirror and the second acoustic mirror comprise a same acoustic reflector. In some aspects, the acoustic wave filter further includes a third unit of resonators disposed proximate the first unit of resonators and on the first side of the acoustic coupling unit; and a fourth unit of resonators disposed proximate the second unit of resonators and on the second side of the acoustic coupling unit, wherein the third unit of resonators and the fourth unit of resonators are in an acoustic communication.

In some aspects, the fourth unit of resonators and the second unit of resonators are in an electrical communication. In some aspects, the third unit of resonators comprises a fifth resonator and a sixth resonator electrically coupled to the fifth resonator, and wherein the fourth unit of resonators comprises a seventh resonator and an eight resonator electrically coupled to the seventh resonator. In some aspects, the fifth resonator comprises a ninth electrode and a tenth electrode, wherein the sixth resonator comprises an eleventh electrode and a twelfth electrode wherein the twelfth electrode of the sixth resonator is disposed adjacent to the acoustic coupling unit and is configured to provide a signal output, and wherein the seventh resonator comprises a thirteenth electrode and a fourteenth electrode, wherein the eighth resonator comprises a fifteenth electrode and a sixteenth electrode, and wherein the thirteenth electrode of the seventh resonator and the fifteenth electrode of the eighth resonator are disposed adjacent to the acoustic coupling unit. In some aspects, a wireless device includes the acoustic wave filter.

In an exemplary aspect, a wireless device is provided. The wireless device includes an acoustic filter. In some aspects, the acoustic filter includes an acoustic coupling layer; a first unit of resonators disposed on a first side of the acoustic coupling layer; and a second unit of resonators disposed on a second side, opposite the first side, of the acoustic coupling layer, wherein the first unit of resonators and the second unit of resonators are in an acoustic communication, wherein the first unit of resonators comprises a first resonator and a second resonator electrically coupled to the first resonator, and wherein the second unit of resonators comprises a third resonator and a fourth resonator electrically coupled to the third resonator.

In some aspects, the first resonator includes a first electrode and a second electrode, and wherein the second electrode of the first resonator is disposed adjacent to the acoustic coupling unit and is configured to receive a signal input. In some aspects, the acoustic filter further includes a third unit of resonators disposed proximate the first unit of resonators and on the first side of the acoustic coupling layer; and a fourth unit of resonators disposed proximate the second unit of resonators and on the second side of the acoustic coupling layer, wherein the third unit of resonators and the fourth unit of resonators are in an acoustic communication.

In an exemplary aspect, a method for operating an acoustic wave filter is provided. The method includes receiving a signal via an input of the acoustic wave filter, wherein the acoustic wave filter comprises i) an acoustic coupling layer, ii) a first resonator and a second resonator disposed on a first side of the acoustic coupling layer, and iii) a third resonator and a fourth resonator disposed on a second side, opposite the first side, of the acoustic coupling layer, wherein the second resonator is electrically coupled to the first resonator, and wherein the fourth resonator is electrically coupled to the third resonator; filtering the signal via the acoustic wave filter; and outputting the signal via an output of the acoustic wave filter.

In some aspects, the first resonator includes a first electrode and a second electrode, wherein the second electrode of the first resonator is disposed adjacent to the acoustic coupling layer, and wherein receiving the signal occurs via the second electrode of the first resonator. In some aspects, the third resonator includes a fifth electrode and a sixth electrode, and wherein the fifth electrode of the third resonator is disposed adjacent to the acoustic coupling layer and is connected to ground, and wherein the fourth resonator comprises a seventh electrode and an eighth electrode, and wherein the seventh electrode of the fourth resonator is disposed adjacent to the acoustic coupling layer, and wherein outputting the signal occurs via the seventh electrode of the fourth resonator.

Additional aspects, features, and advantages of the present disclosure will become apparent from the following detailed description.

### BRIEF DESCRIPTION OF THE DRAWINGS

Illustrative embodiments of the present disclosure will be described with reference to the accompanying drawings, of which:

FIG. 1A illustrates a schematic diagram of a 2-stage coupled resonator filter, according to aspects of the present disclosure.

FIG. 1B illustrates a simplified representation of the 2-stage coupled resonator filter in FIG. 1A, according to aspects of the present disclosure.

FIG. 2A illustrates a schematic diagram of a coupled resonator filter, according to aspects of the present disclosure.

FIG. 2B illustrates a schematic diagram of the coupled resonator filter of FIG. 2A with matching inductors for a large bandwidth operation of the coupled resonator filter, according to aspects of the present disclosure.

FIG. 3A illustrates a schematic diagram of a coupled resonator filter configured in a cascaded configuration, according to aspects of the present disclosure.

FIG. 3B illustrates a schematic diagram of the coupled resonator filter of FIG. 3A with matching inductors for a large bandwidth operation of the coupled resonator filter, according to aspects of the present disclosure.

FIG. 4A shows a plot depicting a linear response comparison between a 2-stage coupled resonator filter having single resonators and a coupled resonator filter having cascaded resonators with inductors, according to aspects of the present disclosure.

FIG. 4B shows a plot depicting a return loss comparison between a 2-stage coupled resonator filter having single resonators and a coupled resonator filter having cascaded resonators with inductors, according to aspects of the present disclosure.

FIG. 5A shows a plot depicting a second harmonic generation (H2) response comparison between a 2-stage coupled resonator filter with single-resonator configuration having single resonators and a coupled resonator filter with cascaded configuration having cascaded resonators with inductors, according to aspects of the present disclosure.

FIG. 5B shows a plot depicting power handling improvements in terms of power density comparison between the 2-stage coupled resonator filter with single-resonator configuration having single resonators and the coupled resonator filter with cascaded configuration having cascaded resonators with inductors, according to aspects of the present disclosure.

FIG. 6 illustrates a flowchart for a method of operating an acoustic wave filter, according to aspects of the present disclosure.

FIG. 7 illustrates a wireless device comprising an acoustic wave filter, according to aspects of the present disclosure.

### DETAILED DESCRIPTION

For the purposes of promoting an understanding of the principles of the present disclosure, reference will now be made to the embodiments illustrated in the drawings, and specific language will be used to describe the same. It is nevertheless understood that no limitation to the scope of the disclosure is intended. Any alterations and further modifications to the described devices, systems, and methods, and any further application of the principles of the present disclosure are fully contemplated and included within the present disclosure as would normally occur to one skilled in the art to which the disclosure relates. In particular, it is fully contemplated that the features, components, and/or steps described with respect to one embodiment may be combined with the features, components, and/or steps described with respect to other embodiments of the present disclosure. For the sake of brevity, however, the numerous iterations of these combinations will not be described separately.

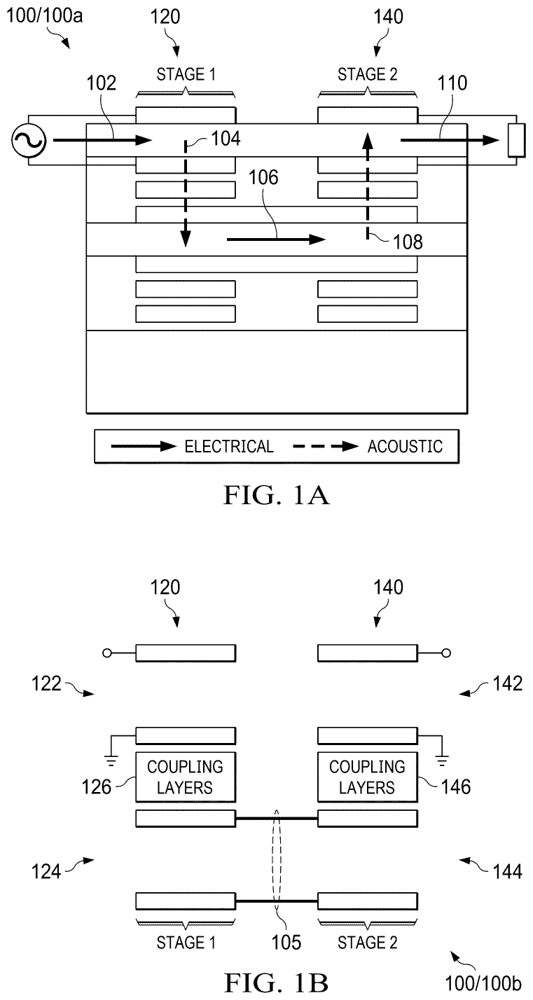

In accordance with one or more embodiments, novel approaches and/or device configurations of coupled resonator filter (CRF) devices, systems, and methods of operating such devices and systems are described in detail with respect to FIGS. 1-7. Various implementations of the coupled resonator filter devices and systems may help improve power handling capabilities of the CRF devices and systems while also help maintain and improve their performances.

FIG. 1A illustrates a schematic diagram 100a of a 2-stage coupled resonator filter 100, according to aspects of the present disclosure. FIG. 1B illustrates a simplified representation 100b of the 2-stage coupled resonator filter 100 of FIG. 1A, according to aspects of the present disclosure. As shown in FIGS. 1A and 1B, the coupled resonator filter 100 includes a first unit of resonators 120 (also referred to herein as “first stage”) and a second unit of resonators 140 (also referred to herein as “second stage”) that are electrically coupled via an interconnect 105. As illustrated in FIG. 1B, the first unit (first stage) of resonators 120 further includes a first resonator 122 and a second resonator 124 that are coupled via an acoustic coupling unit 126, which may be interchangeably referred to herein coupling layers 126 or acoustic coupling layers 126. Similarly, the second unit (second stage) of resonators 140 further includes a third resonator 142 and a fourth resonator 144 that are coupled via an acoustic coupling unit 146, which may be interchangeably referred to herein coupling layers 146 or acoustic coupling layers 146. As illustrated in FIG. 1B, the electrical coupling via the interconnect 105 between the first unit of resonators 120 and the second unit of resonators 140 is implemented via the second resonator 124 of the first unit of resonators 120 and the fourth resonator 144 of the second unit of resonators 140.

During operation of the coupled resonator filter 100, a signal 102 may be applied to the first unit of resonators 120 and the signal gets transmitted through the first unit of resonators 120 as an acoustic signal 104. The acoustic signal 104 may then be converted to an electrical signal 106 and transmitted to the second unit of resonators 140. Once the second unit of resonators 140 receives the electrical signal 106, it can be transmitted through the second resonator 140 as an acoustic signal 108, which is then output as an electrical signal 110, as illustrated in FIG. 1A.

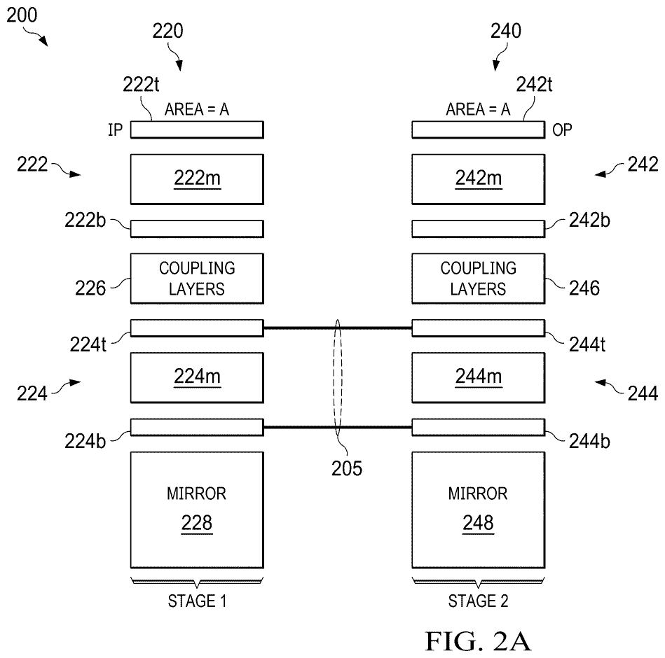

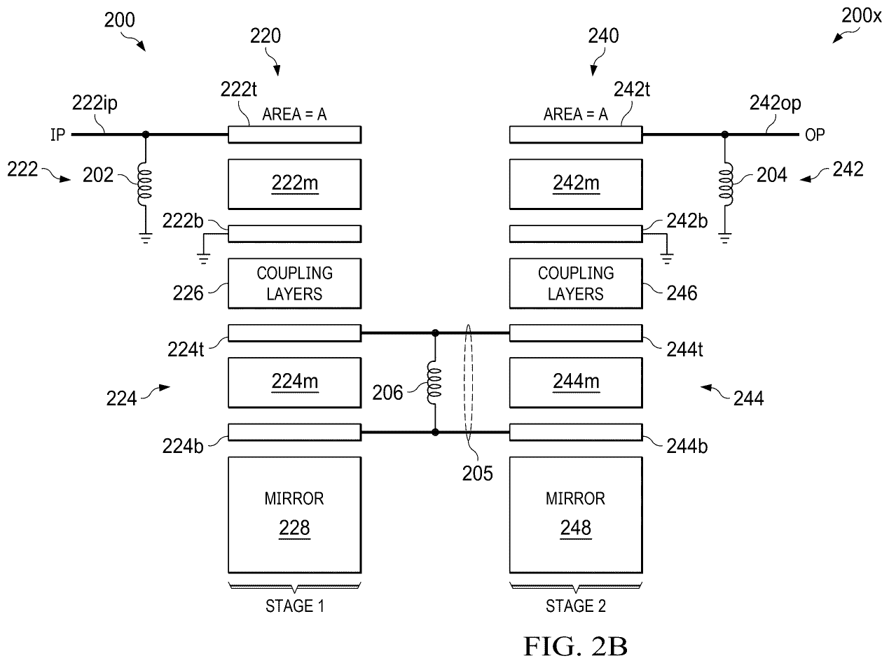

FIG. 2A illustrates a schematic diagram of a coupled resonator filter 200, according to aspects of the present disclosure. As illustrated in FIG. 2A, the coupled resonator filter 200 includes two filter stages, namely stage 1 and stage 2. In one or more implementations, there can be “n” number of stages, where “n” can be any integer. As shown, the coupled resonator filter 200 includes a first unit of resonators 220, which forms stage 1, and a second unit of resonators 240, which forms stage 2, that are electrically coupled via an interconnect 205. As illustrated in FIG. 2A, the first unit of resonators 220 further includes a first resonator 222 and a second resonator 224 that are coupled via an acoustic coupling unit 226, which may be interchangeably referred to herein coupling layers 226 or acoustic coupling layers 226. Similarly, the second unit of resonators 240 further includes a third resonator 242 and a fourth resonator 244 that are coupled via an acoustic coupling unit 246, which may be interchangeably referred to herein coupling layers 246 or acoustic coupling layers 246. Furthermore, the first unit of resonators 220 also includes an acoustic mirror 228 and the second unit of resonators 240 also includes an acoustic mirror 248, as depicted in FIG. 2A. In one or more implementations, the acoustic mirror 228 and/or the acoustic mirror 248 may comprise air. In one or more implementations, the acoustic mirror 228 and/or the acoustic mirror 248 may be disposed on top of, or below, the first unit of resonators 220 and/or the second unit of resonators 240.

As further illustrated in FIG. 2A, the first resonator 222 includes a first electrode 222t, a second electrode 222b, one or more piezoelectric material layers 222m formed between the first electrode 222t and the second electrode 222b. Similarly, the second resonator 224 includes a third electrode 224t, a fourth electrode 224b, one or more piezoelectric material layers 224m formed between the third electrode 224t and the fourth electrode 224b. As further illustrated in FIG. 2A, the third resonator 242 includes a fifth electrode 242t, a sixth electrode 242b, one or more piezoelectric material layers 242m formed between the fifth electrode 242t and the sixth electrode 242b. Similarly, the fourth resonator 244 includes a seventh electrode 244t, an eighth electrode 244b, one or more piezoelectric material layers 244m formed between the seventh electrode 244t and the eighth electrode 244b, as shown in FIG. 2A.

As illustrated in FIG. 2A, the electrical coupling via the interconnect 205 between the first unit of resonators 220 and the second unit of resonators 240 is implemented via the second resonator 224 of the first unit of resonators 220 and the fourth resonator 244 of the second unit of resonators 240. In further specificity, the electrical coupling via the interconnect 205 between the first unit of resonators 220 and the second unit of resonators 240 is implemented between the third electrode 224t and the seventh electrode 244t, and the fourth electrode 224b and the eighth electrode 244b, as shown in FIG. 2A.

FIG. 2B illustrates a schematic diagram 200x of the coupled resonator filter 200 of FIG. 2A with matching inductors for a large bandwidth operation of the coupled resonator filter, according to aspects of the present disclosure. As shown in the schematic diagram 200x of the coupled resonator filter 200 illustrated in FIG. 2B, the coupled resonator filter 200 may be configured for a signal input via input port 222ip at the first electrode 222t of the first resonator 222 with a ground at the second electrode 222b. In one or more implementations, the first electrode 222t of the first resonator 222 may be coupled to an inductor 202, which is grounded on the other end, for a large bandwidth operation of the coupled resonator filter 200, as shown in FIG. 2B. Similarly, for a large bandwidth operation, the coupled resonator filter 200 may also be configured for a signal output via output port 242op at the fifth electrode 242t of the third resonator 242 with a ground at the sixth electrode 242b. In one or more implementations, the fifth electrode 242t of the third resonator 242 may be coupled to an inductor 204, which is grounded on the other end, for a large bandwidth operation of the coupled resonator filter 200, as shown in FIG. 2B. Moreover, as illustrated in the schematic diagram 200x FIG. 2B, an inductor 206 can be coupled across the interconnect 205 that is implemented between the third electrode 224t and the seventh electrode 244t, and the fourth electrode 224b and the eighth electrode 244b, as shown in FIG. 2A.

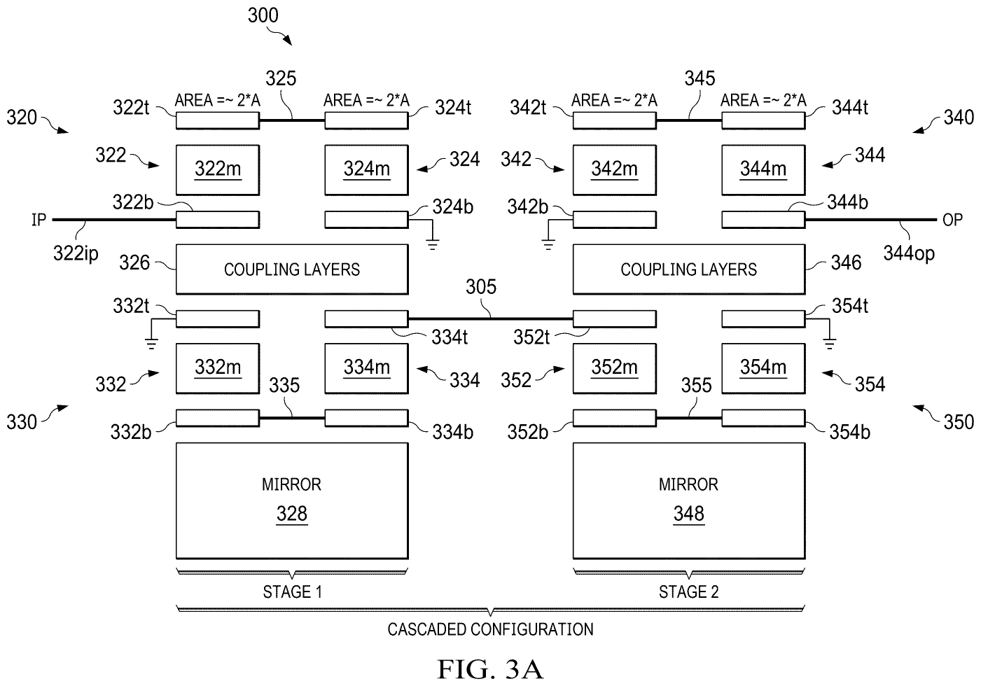

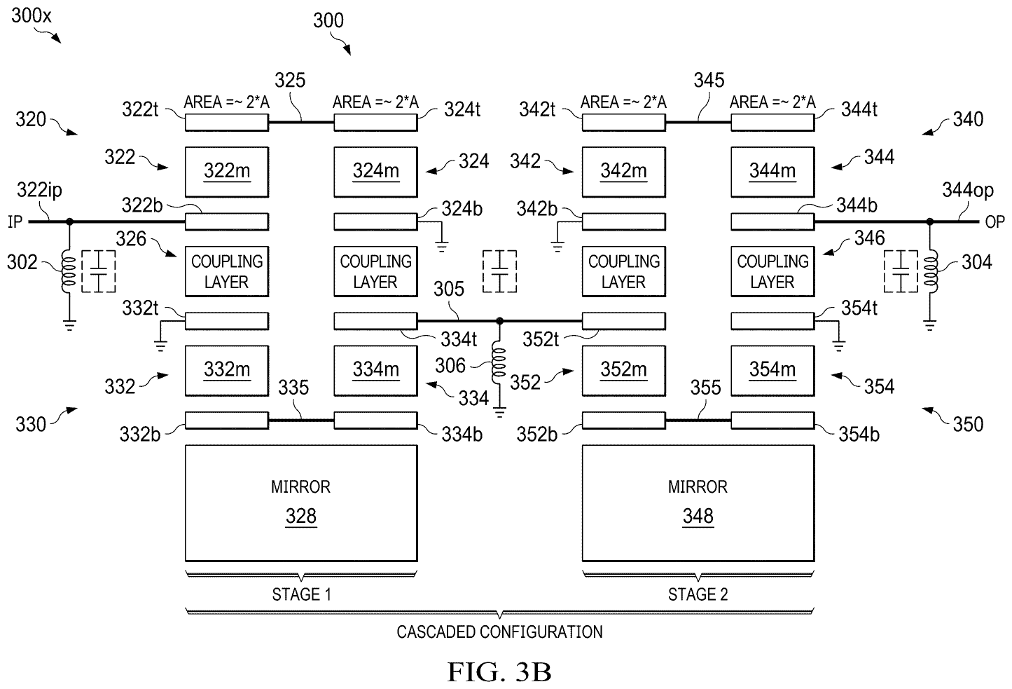

FIG. 3A illustrates a schematic diagram of a coupled resonator filter 300 configured in a cascaded configuration, according to aspects of the present disclosure. As shown in FIG. 3A, the coupled resonator filter 300 includes a plurality of units of resonators in a cascaded configuration that includes multiple stages. As shown, the coupled resonator filter 300 includes a first unit of resonators 320, a second unit of resonators 330, a third unit of resonators 340, and a fourth unit of resonators 350. Although shown as a 2-stage coupled resonator filter in FIG. 3A, where the first unit of resonators 320 and the second unit of resonators 330 form a first stage (shown as “stage 1” in FIG. 3A), and the third unit of resonators 340 and the fourth unit of resonators 350 form a second stage (shown as “stage 2” in FIG. 3A), the coupled resonator filter 300 may include more than two stages, in accordance with one or more embodiments. In some embodiments, the coupled resonator filter 300 may include a single stage of resonators, for example, having the first unit of resonators 320 and the second unit of resonators 330.

As further illustrated in FIG. 3A, the first unit of resonators 320 further includes a first resonator 322 and a second resonator 324, the second unit of resonators 330 further includes a third resonator 332 and a fourth resonator 334, the third unit of resonators 340 further includes a fifth resonator 342 and a sixth resonator 344, and the fourth unit of resonators 350 further includes a seventh resonator 352 and an eighth resonator 354. Each of the resonators 322, 324, 332, 334, 342, 344, 352, and 354 include a top electrode, a bottom electrode, and one or more piezoelectric material layers formed between the top electrode and the bottom electrode, as illustrated in FIG. 3A. In particular, the first resonator 322 includes a first electrode 322t, a second electrode 322b, and one or more piezoelectric material layers 322m formed between the first electrode 322t and the second electrode 322b. Similarly, the second resonator 324 includes a third electrode 324t, a fourth electrode 324b, and one or more piezoelectric material layers 324m formed between the third electrode 324t and the fourth electrode 324b. The third resonator 332 includes a fifth electrode 332t, a sixth electrode 332b, and one or more piezoelectric material layers 332m formed between the fifth electrode 332t and the sixth electrode 332b. The fourth resonator 334 includes a seventh electrode 334t, an eighth electrode 334b, and one or more piezoelectric material layers 334m formed between the seventh electrode 334t and the eighth electrode 334b. The fifth resonator 342 includes a nineth electrode 342t, a tenth electrode 342b, and one or more piezoelectric material layers 342m formed between the nineth electrode 342t and the tenth electrode 342b. The sixth resonator 344 includes an eleventh electrode 344t, a twelfth electrode 344b, and one or more piezoelectric material layers 344m formed between the eleventh electrode 344t and the twelfth electrode 344b. The seventh resonator 352 includes a thirteenth electrode 352t, a fourteenth electrode 352b, and one or more piezoelectric material layers 352m formed between the thirteenth electrode 352t and the fourteenth electrode 352b. The eighth resonator 354 includes a fifteenth electrode 354t, a sixteenth electrode 354b, and one or more piezoelectric material layers 354m formed between the fifteenth electrode 354t and the sixteenth electrode 354b.

As further illustrated in FIG. 3A, the first unit of resonators 320, which includes the first resonator 322 and the second resonator 324 are coupled to the second unit of resonators 330, which includes the third resonator 332 and the fourth resonator 334, via an acoustic coupling unit 326, which may be interchangeably referred to herein coupling layers 326 or acoustic coupling layers 326. Similarly, the third unit of resonators 340, which includes the fifth resonator 342 and the sixth resonator 344, are coupled to the fourth unit of resonators 350, which includes the seventh resonator 352 and the eighth resonator 354 via an acoustic coupling unit 346, which may be interchangeably referred to herein coupling layers 346 or acoustic coupling layers 346. Furthermore, while the second unit of resonators 330 are coupled to the first unit of resonators 320 on a first side of the second unit of resonators 330, the second unit of resonators 330 are further coupled to an acoustic mirror 328 on a second side of the second unit of resonators 330. Similarly, while the fourth unit of resonators 350 are coupled to the third unit of resonators 340 on a first side of the fourth unit of resonators 350, the fourth unit of resonators 350 are further coupled to an acoustic mirror 348 on a second side of the fourth unit of resonators 350, as depicted in FIG. 3A.

As shown in FIG. 3A, the electrical coupling between the first resonator 322 and the second resonator 324 is implemented via an interconnect 325. Similarly, the electrical coupling between the third resonator 332 and the fourth resonator 334 is implemented via an interconnect 335, the electrical coupling between the fifth resonator 342 and the sixth resonator 344 is implemented via an interconnect 345, and the electrical coupling between the seventh resonator 352 and the eighth resonator 354 is implemented via an interconnect 355, as shown in FIG. 3A.

As further illustrated in FIG. 3A, the coupled resonator filter 300 may be configured for a signal input via input port 322ip at the second electrode 322b of the first resonator 322 with a ground at the fourth electrode 324b of the second resonator 324. Once the signal is input via the first unit of resonators 320, the signal may be transmitted from the first unit of resonators 320 to the second unit of resonators 330 via the acoustic coupling unit 326 as an acoustic signal. The acoustic signal may be converted to an electrical signal in the second unit of resonators 330 and the electrical signal may be transmitted from the second unit of resonators 330 to the fourth unit of resonators 350 via an interconnect 305. As shown in FIG. 3A, the electrical signal may be transmitted across the second unit of resonators 330 and the fourth unit of resonators 350 via the interconnect 305, which is the electrical connection implemented between the seventh electrode 334t of the fourth resonator 334 and the thirteenth electrode 352t of the seventh resonator 352.

As illustrated in FIG. 3A, the second unit of resonators 330 may be configured such that the fifth electrode 332t of the third resonator 332 is coupled to a ground, while the sixth electrode 332b of the third resonator 332 is electrically coupled to the eighth electrode 334b of the fourth resonator 334 via the interconnect 335. Similarly, the fourth unit of resonators 350 may be configured such that the fifteenth electrode 354t of the eighth resonator 354 is coupled to a ground, while the sixteenth electrode 354b is electrically coupled to the fourteenth electrode 352b of the seventh resonator 352 via the interconnect 355. In addition, the third unit of resonators 340 may be configured such that the tenth electrode 342b of the fifth resonator 342 is coupled to a ground, while the nineth electrode 342t is electrically coupled to the eleventh electrode 344t of the sixth resonator 344 via the interconnect 345. As illustrated in FIG. 3A, the coupled resonator filter 300 may be configured for a signal output via output port 344op at the twelfth electrode 344b of the sixth resonator 344.

FIG. 3B illustrates a schematic diagram 300x of the coupled resonator filter 300 of FIG. 3A with matching inductors for a large bandwidth operation of the coupled resonator filter, according to aspects of the present disclosure. As shown in the schematic diagram 300x of the coupled resonator filter 300 illustrated in FIG. 3B, the coupled resonator filter 300 can be configured for the signal input via the input port 322ip at the second electrode 322b of the first resonator 322 with the ground at the fourth electrode 324b of the second resonator 324. In one or more implementations, the second electrode 322b of the first resonator 322 may be coupled to an inductor 302, which is grounded on the other end, for a large bandwidth operation of the coupled resonator filter 300, as shown in FIG. 3B. Similarly, for a large bandwidth operation, the coupled resonator filter 300 may also be configured for a signal output via output port 344op at the twelfth electrode 344b of the sixth resonator 344 with the ground at the tenth electrode 342b. In one or more implementations, the twelfth electrode 344b of the sixth resonator 344 may be coupled to an inductor 304, which is grounded on the other end, for a large bandwidth operation of the coupled resonator filter 300, as shown in FIG. 3B. Moreover, as illustrated in the schematic diagram 300x FIG. 3B, an inductor 306 can be coupled to the interconnect 305 that is implemented between the seventh electrode 334t of the fourth resonator 334 and the thirteenth electrode 352t of the seventh resonator 352, as shown in FIG. 3B.

As discussed herein, the coupled resonator filter 300 of FIGS. 3A and 3B include a plurality of resonators connected in a cascaded configuration, which helps maintain the symmetric nature of the coupled resonator filter device that can provide better power handling capability as well as the non-linear performance enhancement compared to resonators implemented in non-cascaded configurations. Furthermore, implementing inductors as described with respect to FIGS. 2B and 3B enable the coupled resonator filters 200 and 300 to perform as large bandwidth filters. As noted in FIGS. 2A, 2B, 3A, and 3B, the novel configurations implement coupling of one or more coupled resonator filter resonators in a cascaded configuration so that the area of each coupled resonator filter resonator increases although the individual coupled resonator filter resonators may be smaller. In other words, when the top resonator of the coupled resonator filter is excited, the acoustic energy generated in the top resonator is coupled to the bottom resonator through the acoustic coupling units/layers. Due to the piezo electric behavior of the bottom resonator, electric energy is generated in the bottom resonators that are electrically connected. In some implementations, the coupled resonator filter with just one resonator per stage might have power handling issue due to the small size of the resonator or high input powers. In addition, harmonics may be more effectively cancelled within the coupled resonator filter, which in turn may help improve non-linear performance of the coupled resonator filter. For example, since the resonators are implemented in a cascaded configuration, the size of each resonator is approximately doubled which decreases power density in the resonators and improves power handling. In addition, due to the cascaded configuration, better cancellation of harmonic components is possible. Without proper care, the cascading may result in degradation of in-band or out-band performance due to the additional capacitances through the coupling layers.

The cascaded configuration illustrated in FIGS. 3A and 3B show optimal performance compared with other configurations that can be envisaged because the capacitances in the coupling layers appear at the input and outputs of the coupled resonator filter 300 and in the interstage match. As such, these capacitances can be compensated for using shunt inductors. Incidentally, these inductors are generally needed for larger bandwidth filters even in the case where the resonators are not cascaded. In some aspects, compensating for capacitances results in additional loss. However, this may be better than other configurations where the capacitance through the coupling layers appears as a cross-coupling which degrades filter rejection. An alternative option that can potentially avoid the matching inductors is to use higher k2e piezo electric material. However, the resonator size may be smaller for higher coupling piezo to achieve similar RL (Return Loss) levels. In such instances, the resonator areas achieved by using inductors may be larger compared to using piezo with higher coupling.

### Examples

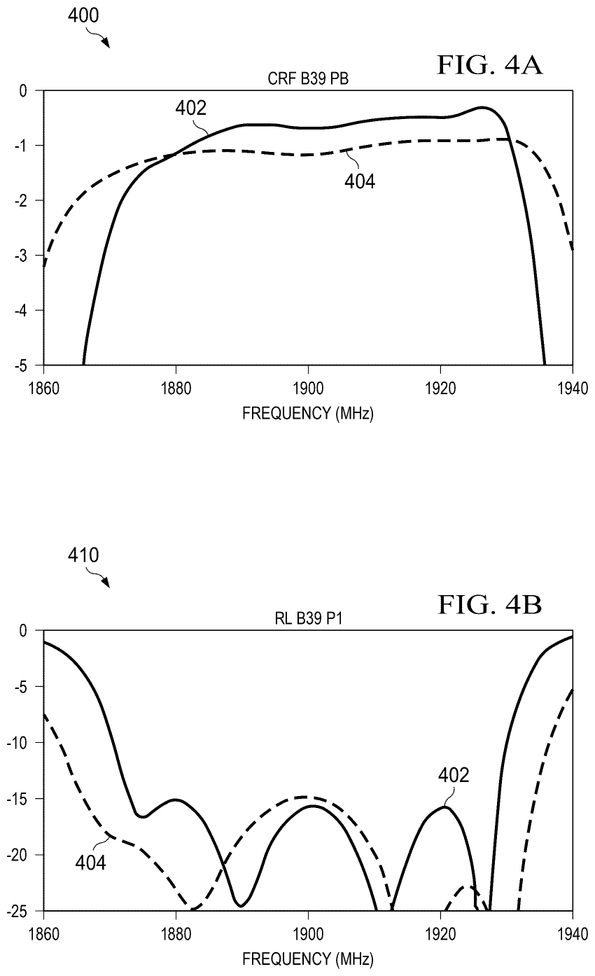

An example filter with passband from 1880-1920 MHz is chosen as a case study in this report. FIG. 4A shows a plot 400 depicting a linear response comparison between a 2-stage coupled resonator filter 402 having single resonators and a 2-stage coupled resonator filter with cascaded configuration 404 having cascaded resonators with inductors, according to aspects of the present disclosure. FIG. 4B shows a plot 410 depicting a return loss comparison between a 2-stage coupled resonator filter having single resonators and a 2-stage coupled resonator filter having cascaded resonators with inductors, according to aspects of the present disclosure. As shown in the plots 400 and 410, the cascaded configuration 404 has slightly wider bandwidth and higher loss due to the addition of inductors. Overall, by using the cascaded configuration 404, the linear performance of the filter is fairly retained. The advantages of using cascaded configuration 404, compared to single resonator configuration 402 in terms of power handling and non-linearity is shown below.

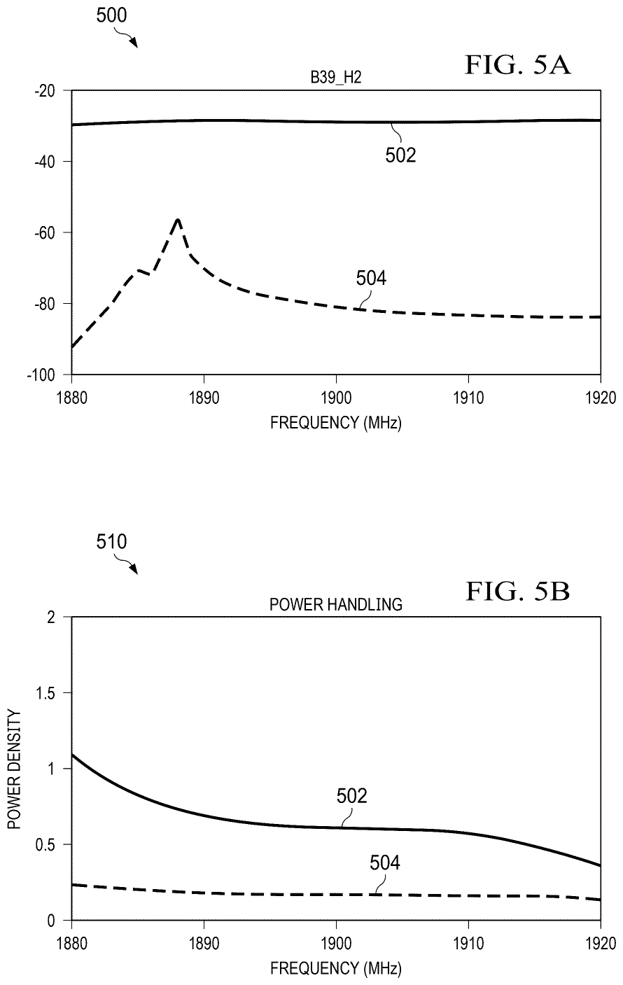

FIG. 5A shows a plot 500 depicting a second harmonic generation (H2) response comparison between a 2-stage coupled resonator filter with single-resonator configuration 502 having single resonators and a coupled resonator filter with cascaded configuration 504 having cascaded resonators with inductors, according to aspects of the present disclosure. As illustrated in FIG. 5A, the plot 500 shows the second harmonic generation (H2) response for fixed input power of 25 dBm.

FIG. 5B shows a plot 510 depicting power handling improvements in terms of power density (W/mm²) comparison for an input power of 25 dBm between the 2-stage coupled resonator filter with single-resonator configuration 502 having single resonators and the coupled resonator filter with cascaded configuration 504 having cascaded resonators with inductors, according to aspects of the present disclosure. As depicted in FIG. 5B, the plot 510 shows significant improvement in H2 response by using the cascaded configuration 504 due to 180-degree phase difference between the currents in the cascaded resonators, which helps improve cancellation of the harmonics generated. For simplicity, the power density on a resonator that has the highest dissipated power is shown. It is also observed that power density, which is defined as power dissipated per unit area of the resonator, is improved approximately 4 times due to the cascaded configuration 504. For comparison, in this example the area of each resonator for non-cascaded configuration, i.e., the 2-stage coupled resonator filter 502, is 2.52e−8 m² while the area for each cascaded resonator is 4.7e−8 m². In other words, it is shown that by using the cascaded configuration 504, both linearity and power handling capability of the resonator can be improved.

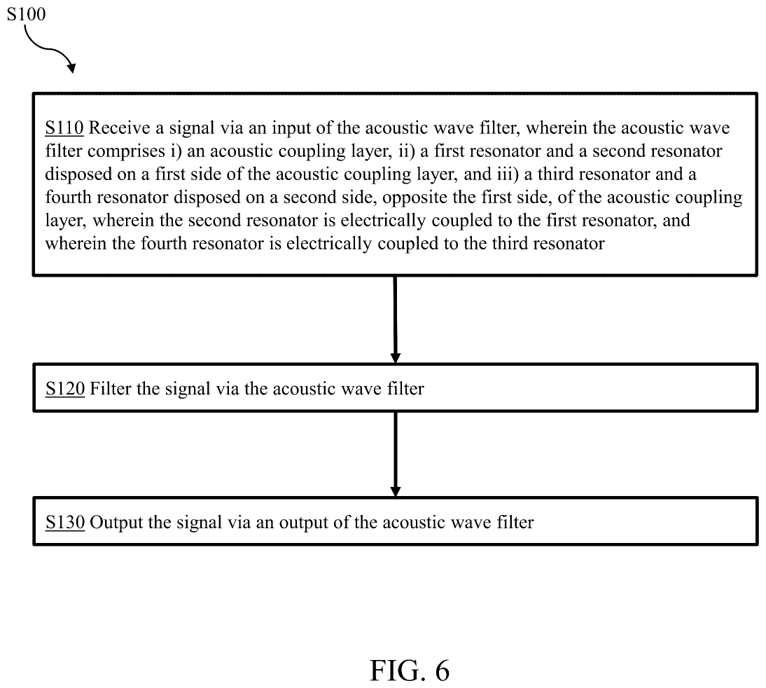

FIG. 6 illustrates a flowchart for a method S100 of operating an acoustic wave filter, according to aspects of the present disclosure. As illustrated in FIG. 6, the method S100 may include, at step S110, receiving a signal via an input of the acoustic wave filter, wherein the acoustic wave filter comprises i) an acoustic coupling layer, ii) a first resonator and a second resonator disposed on a first side of the acoustic coupling layer, and iii) a third resonator and a fourth resonator disposed on a second side, opposite the first side, of the acoustic coupling layer, wherein the second resonator is electrically coupled to the first resonator, and wherein the fourth resonator is electrically coupled to the third resonator; at step S120, filtering the signal via the acoustic wave filter; and at step S130, outputting the signal via an output of the acoustic wave filter.

In one or more embodiments of the method S100, the first resonator includes a first electrode and a second electrode, wherein the second electrode of the first resonator is disposed adjacent to the acoustic coupling layer, and wherein receiving the signal occurs via the second electrode of the first resonator. In one or more embodiments of the method S100, the third resonator includes a fifth electrode and a sixth electrode, and wherein the fifth electrode of the third resonator is disposed adjacent to the acoustic coupling layer and is connected to ground, and wherein the fourth resonator comprises a seventh electrode and an eighth electrode, and wherein the seventh electrode of the fourth resonator is disposed adjacent to the acoustic coupling layer, and wherein outputting the signal occurs via the seventh electrode of the fourth resonator.

In accordance with one or more embodiments, the method S100 may be used for operating an acoustic wave filter having a coupled resonator filter with a cascaded configuration. The acoustic wave filter with the cascaded configuration may include an acoustic coupling unit, a first unit of resonators disposed on a first side of the acoustic coupling unit, the first unit of resonators comprising a first resonator and a second resonator electrically coupled to the first resonator, and a second unit of resonators disposed on a second side, opposite the first side, of the acoustic coupling unit such that the first unit of resonators and the second unit of resonators are in an acoustic communication. In one or more embodiments, the first resonator includes a first electrode and a second electrode, and wherein the second electrode of the first resonator is disposed adjacent to the acoustic coupling unit and is configured to receive a signal input.

In one or more embodiments, the second resonator includes a third electrode and a fourth electrode, and wherein the fourth electrode of the second resonator is disposed adjacent to the acoustic coupling unit and is connected to ground. In one or more embodiments, the first electrode of the first resonator and the third electrode of the second resonator are in an electrical communication. In one or more embodiments, the second unit of resonators comprises a third resonator and a fourth resonator electrically coupled to the third resonator. In one or more embodiments, the third resonator comprises a fifth electrode and a sixth electrode, and wherein the fifth electrode of the third resonator is disposed adjacent to the acoustic coupling unit and is connected to ground. In one or more embodiments, the fourth resonator comprises a seventh electrode and an eighth electrode, and wherein the seventh electrode of the fourth resonator is disposed adjacent to the acoustic coupling unit and configured to provide a signal output. In one or more embodiments, the sixth electrode of the third resonator and the eighth electrode of the fourth resonator are in an electrical communication.

In various embodiments, the first unit of resonators, the acoustic coupling unit, and the second unit of resonators form a resonator stack. In one or more embodiments, the acoustic wave filter includes a first acoustic mirror disposed adjacent to the first unit of resonators of the resonator stack and away from the acoustic coupling unit, a second acoustic mirror disposed adjacent to the second unit of resonators of the resonator stack and away from the acoustic coupling unit, or a combination thereof. In one or more embodiments, the first acoustic mirror and the second acoustic mirror comprise the same acoustic reflector. In one or more embodiments, the acoustic wave filter further includes a third unit of resonators disposed proximate the first unit of resonators and on the first side of the acoustic coupling unit; and a fourth unit of resonators disposed proximate the second unit of resonators and on the second side of the acoustic coupling unit, wherein the third unit of resonators and the fourth unit of resonators are in an acoustic communication.

In one or more embodiments, the fourth unit of resonators and the second unit of resonators are in an electrical communication. In one or more embodiments, the third unit of resonators comprises a fifth resonator and a sixth resonator electrically coupled to the fifth resonator, and wherein the fourth unit of resonators comprises a seventh resonator and an eight resonator electrically coupled to the seventh resonator. In some aspects, the fifth resonator comprises a ninth electrode and a tenth electrode, wherein the sixth resonator comprises an eleventh electrode and a twelfth electrode wherein the twelfth electrode of the sixth resonator is disposed adjacent to the acoustic coupling unit and is configured to provide a signal output, and wherein the seventh resonator comprises a thirteenth electrode and a fourteenth electrode, wherein the eighth resonator comprises a fifteenth electrode and a sixteenth electrode, and wherein the thirteenth electrode of the seventh resonator and the fifteenth electrode of the eighth resonator are disposed adjacent to the acoustic coupling unit. In one or more embodiments, a wireless device includes the acoustic wave filter.

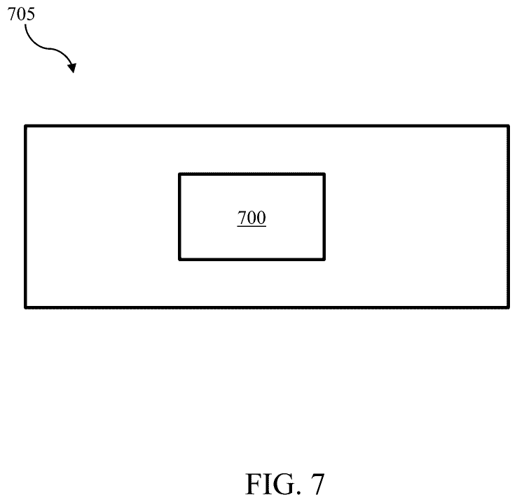

FIG. 7 illustrates a wireless device 705 comprising an acoustic filter 700, according to aspects of the present disclosure. As illustrated in FIG. 7, the wireless device 705 includes the acoustic filter 705 (also interchangeably referred to herein as acoustic wave filter 705), which may be a coupled resonator filter with a cascaded configuration, in accordance with one or more embodiments. In some implementations, the wireless device 705 may be any wireless communication device, such as for example, but not limited to, a cellular device, a satellite communication device, a wi-fi device, a radar, a global position system device, or any wireless device that can be used for filtering radio frequency signals.

In one or more embodiments, the acoustic filter/acoustic wave filter 705 may include an acoustic coupling layer; a first unit of resonators disposed on a first side of the acoustic coupling layer; and a second unit of resonators disposed on a second side, opposite the first side, of the acoustic coupling layer, wherein the first unit of resonators and the second unit of resonators are in an acoustic communication, wherein the first unit of resonators comprises a first resonator and a second resonator electrically coupled to the first resonator, and wherein the second unit of resonators comprises a third resonator and a fourth resonator electrically coupled to the third resonator.

In one or more embodiments, the first resonator includes a first electrode and a second electrode, and wherein the second electrode of the first resonator is disposed adjacent to the acoustic coupling unit and is configured to receive a signal input. In one or more embodiments, the acoustic filter further includes a third unit of resonators disposed proximate the first unit of resonators and on the first side of the acoustic coupling layer; and a fourth unit of resonators disposed proximate the second unit of resonators and on the second side of the acoustic coupling layer, wherein the third unit of resonators and the fourth unit of resonators are in an acoustic communication.

In accordance with one or more implementations, the disclosed cascaded configurations of the coupled resonator filter devices and systems can help improve the power handling capability of coupled resonator filters while also maintain or, perhaps improve, the non-linear performance behavior of the coupled resonator filters. Thus, the various aspects, embodiments, and implementations of the disclosure advantageously provide device configurations that can help improve power handling capabilities of cascaded coupled resonator filters.

Persons skilled in the art will recognize that the apparatus, systems, and methods described above can be modified in various ways. Accordingly, persons of ordinary skill in the art will appreciate that the embodiments encompassed by the present disclosure are not limited to the particular exemplary embodiments described above. In that regard, although illustrative embodiments have been shown and described, a wide range of modification, change, and substitution is contemplated in the foregoing disclosure. It is understood that such variations may be made to the foregoing without departing from the scope of the present disclosure. Accordingly, it is appropriate that the appended claims be construed broadly and in a manner consistent with the present disclosure.

1. An acoustic wave filter, comprising:
an acoustic coupling unit;
a first unit of resonators disposed on a first side of the acoustic coupling unit, the first unit of resonators comprising a first resonator and a second resonator electrically coupled to the first resonator; and
a second unit of resonators disposed on a second side, opposite the first side, of the acoustic coupling unit such that the first unit of resonators and the second unit of resonators are in an acoustic communication,
wherein the first resonator comprises a first electrode and a second electrode, and
wherein the second electrode of the first resonator is disposed adjacent to the acoustic coupling unit and is configured to receive a signal input.

2. The acoustic wave filter of claim 1, wherein the second resonator comprises a third electrode and a fourth electrode, and wherein the fourth electrode of the second resonator is disposed adjacent to the acoustic coupling unit and is connected to ground.

3. The acoustic wave filter of claim 1, wherein the first electrode of the first resonator and the third electrode of the second resonator are in an electrical communication.

4. The acoustic wave filter of claim 1, wherein the second unit of resonators comprises a third resonator and a fourth resonator electrically coupled to the third resonator.

5. The acoustic wave filter of claim 4, wherein the third resonator comprises a fifth electrode and a sixth electrode, and wherein the fifth electrode of the third resonator is disposed adjacent to the acoustic coupling unit and is connected to ground.

6. The acoustic wave filter of claim 4, wherein the fourth resonator comprises a seventh electrode and an eighth electrode, and wherein the seventh electrode of the fourth resonator is disposed adjacent to the acoustic coupling unit and configured to provide a signal output.

7. The acoustic wave filter of claim 4, wherein the sixth electrode of the third resonator and the eighth electrode of the fourth resonator are in an electrical communication.

8. The acoustic wave filter of claim 1, wherein the first unit of resonators, the acoustic coupling unit, and the second unit of resonators form a resonator stack, further comprising:
a first acoustic mirror disposed adjacent to the first unit of resonators of the resonator stack and away from the acoustic coupling unit,
a second acoustic mirror disposed adjacent to the second unit of resonators of the resonator stack and away from the acoustic coupling unit, or
a combination thereof.

9. The acoustic wave filter of claim 8, wherein the first acoustic mirror and the second acoustic mirror comprise a same acoustic reflector.

10. The acoustic wave filter of claim 1, further comprising:
a third unit of resonators disposed proximate the first unit of resonators and on the first side of the acoustic coupling unit; and
a fourth unit of resonators disposed proximate the second unit of resonators and on the second side of the acoustic coupling unit,
wherein the third unit of resonators and the fourth unit of resonators are in an acoustic communication.

11. The acoustic wave filter of claim 10, wherein the fourth unit of resonators and the second unit of resonators are in an electrical communication.

12. The acoustic wave filter of claim 10, wherein the third unit of resonators comprises a fifth resonator and a sixth resonator electrically coupled to the fifth resonator, and wherein the fourth unit of resonators comprises a seventh resonator and an eight resonator electrically coupled to the seventh resonator.

13. The acoustic wave filter of claim 12, wherein the fifth resonator comprises a ninth electrode and a tenth electrode, wherein the sixth resonator comprises an eleventh electrode and a twelfth electrode wherein the twelfth electrode of the sixth resonator is disposed adjacent to the acoustic coupling unit and is configured to provide a signal output, and
wherein the seventh resonator comprises a thirteenth electrode and a fourteenth electrode, wherein the eighth resonator comprises a fifteenth electrode and a sixteenth electrode, and wherein the thirteenth electrode of the seventh resonator and the fifteenth electrode of the eighth resonator are disposed adjacent to the acoustic coupling unit.

14. A wireless device comprising the acoustic wave filter of claim 1.

15. A wireless device, comprising:
an acoustic filter comprising:
an acoustic coupling layer;
a first unit of resonators disposed on a first side of the acoustic coupling layer; and a second unit of resonators disposed on a second side, opposite the first side, of the acoustic coupling layer,
wherein the first unit of resonators and the second unit of resonators are in an acoustic communication,
wherein the first unit of resonators comprises a first resonator and a second resonator electrically coupled to the first resonator, and
wherein the second unit of resonators comprises a third resonator and a fourth resonator electrically coupled to the third resonator.

16. The wireless device of claim 15, wherein the first resonator comprises a first electrode and a second electrode, and wherein the second electrode of the first resonator is disposed adjacent to the acoustic coupling unit and is configured to receive a signal input.

17. The wireless device of claim 15, wherein the acoustic filter further comprises:
a third unit of resonators disposed proximate the first unit of resonators and on the first side of the acoustic coupling layer; and
a fourth unit of resonators disposed proximate the second unit of resonators and on the second side of the acoustic coupling layer,
wherein the third unit of resonators and the fourth unit of resonators are in an acoustic communication.

18. A method for operating an acoustic wave filter, comprising:
receiving a signal via an input of the acoustic wave filter,
wherein the acoustic wave filter comprises i) an acoustic coupling layer, ii) a first resonator and a second resonator disposed on a first side of the acoustic coupling layer, and iii) a third resonator and a fourth resonator disposed on a second side, opposite the first side, of the acoustic coupling layer,
wherein the second resonator is electrically coupled to the first resonator, and
wherein the fourth resonator is electrically coupled to the third resonator;
filtering the signal via the acoustic wave filter; and
outputting the signal via an output of the acoustic wave filter.

19. The method of claim 18, wherein the first resonator comprises a first electrode and a second electrode, wherein the second electrode of the first resonator is disposed adjacent to the acoustic coupling layer, and wherein receiving the signal occurs via the second electrode of the first resonator.

20. The method of claim 19, wherein the third resonator comprises a fifth electrode and a sixth electrode, and wherein the fifth electrode of the third resonator is disposed adjacent to the acoustic coupling layer and is connected to ground, and
wherein the fourth resonator comprises a seventh electrode and an eighth electrode, and wherein the seventh electrode of the fourth resonator is disposed adjacent to the acoustic coupling layer, and wherein outputting the signal occurs via the seventh electrode of the fourth resonator.
